(19) United States
(12) Patent Application Publication
(10) Pub. No.: US 2020/0150156 A1
(43) Pub. Date: May 14, 2020

(54) Rotary Tool Diagnosis System

(71) Applicant: Hitachi, Ltd., Tokyo (JP)

(72) Inventors: Kazuo ONO, Tokyo (JP); Kouji MATSUDA, Tokyo (JP); Takuma NISHIMURA, Tokyo (JP)

(21) Appl. No.: 16/676,852

(22) Filed: Nov. 7, 2019

(30) Foreign Application Priority Data
Nov. 14, 2018 (JP) 2018-213559

(51) Int. Cl. G01R 19/145; G01R 19/25; G01M 15/02

(52) U.S. Cl. CPC G01R 19/145; G06Q 50/06; G01M 15/02; G01R 19/2513

(57) ABSTRACT

A rotary tool diagnosis system according to one aspect of the present invention includes a first current detector, a second current detector, and a signal processing device. The first current detector detects a current of at least one power line connected to a first electric motor that rotates a rotary tool. The second current detector detects a current of at least one power line connected to a second electric motor that is used for moving the rotary tool. The signal processing device triggers based on a result of processing on an output signal of the second current detector and starts recording of an output signal from the first current detector.

### BACKGROUND OF THE INVENTION

### 1. Field of the Invention

The present invention relates to a rotary tool diagnosis system for diagnosing a rotary tool such as a cutting tool.

### 2. Description of the Related Art

Machining of metal and the like with a rotary tool is used in various manufacturing sites. Generally, a material such as iron is processed using a cutting tool such as a drill or an end mill. If a cutting tool breaks during the processing of a workpiece, the quality of the workpiece may be affected. Therefore, it is necessary to use a cutting tool with a sufficient life such that the workpiece is not damaged during processing. However, frequently changing a cutting tool leads to an increase in manufacturing cost. Therefore, it is preferable to use a cutting tool for an appropriate period and number of times and replace the cutting tool at an appropriate timing.

As a method for determining deterioration of a cutting tool, a method is practically used which records the time and number of times of use of the cutting tool and compares these values with empirically known values until deterioration. However, in this deterioration determination method, the actual life may deviate from the empirically predicted life due to life variations of a cutting tool due to manufacturing variations of cutting tools.

On the other hand, a method is known in which the magnitude of a load of an electric motor used for machining is determined from the magnitude of a torque generated by the electric motor to determine that a cutting tool has deteriorated when this torque meets a certain magnitude and condition. When a cutting tool is deteriorated, the torque required for machining becomes larger than normal (before deterioration), and therefore it is possible to determine deterioration by comparing the torque at the normal time and the torque at the time of machining. With this determination method, diagnosis based on actual measurement can be performed, and compared to diagnosis based on experience, highly accurate deterioration diagnosis that is not affected by manufacturing variations of a cutting tool itself can be performed.

In JP 2011-020221 A, a method is described in which a radio-frequency current sensor is attached to a spindle motor of a processing machine, a current waveform obtained by the radio-frequency current sensor is sampled by a predictive detection device, and a breakage of a rotary blade is predicted from a time-series change of a recorded actual load current waveform.

JP 2011-118840 A discloses a technique for measuring load torque while measuring the load torque of a motor against a machining program as a motor load torque measurement function. In the method described in JP 2011-118840 A, only the necessary measurement section is measured, such that the storage capacity of the storage device can be reduced compared to the method described in JP 2011-020221 A, and the processing capability of a computer used for analysis can also be made relatively small.

### SUMMARY OF THE INVENTION

As described above, it is possible to accurately diagnose the deterioration of a cutting tool by measuring the current and torque generated by an electric motor. However, the known diagnosis methods have the following problems.

For example, in the method described in JP 2011-020221 A, the amount of data to be stored and analyzed becomes enormous due to the radio-frequency sampling, and measurement and analysis require a high-capacity storage device and an analytical computer with high calculation capability. In addition, a method for triggering to acquire the data of a rotary blade has not been described, and it is necessary for a person to manually turn on a recording switch of a prediction detection device or keep recording continuously. For this reason, data will continue to be recorded even during the time when processing is paused, resulting in an increase in storage capacity and time and power required for analysis.

On the other hand, the technology described in JP 2011-118840 A cannot be applied unless the machining program and machining sequence of a processing machine are disclosed, and the cost of a linkage mechanism with a control controller mounted on the processing machine, etc. is increased.

The present invention has been made in consideration of the above situation, and an object of the present invention is to more easily grasp the operation timing of a rotary tool and diagnose the rotary tool without information on the machining program and machining sequence of the processing machine.

A rotary tool diagnosis system according to one aspect of the present invention includes a first current detector, a second current detector, and a signal processing device. The first current detector detects a current of at least one power line connected to a first electric motor that rotates a rotary tool. The second current detector detects a current of at least one power line connected to a second electric motor that is used for moving the rotary tool. The signal processing device triggers based on a result of processing on an output signal of the second current detector to start recording of an output signal from the first current detector.

According to at least one aspect of the present invention, even when the machining program and machining sequence of a processing machine are not disclosed, a rotary tool can be diagnosed by grasping an operation timing of the rotary tool with a simpler configuration.

Issues, configurations, and effects other than the above are clarified by descriptions of the following embodiments.

### BRIEF DESCRIPTION OF THE DRAWINGS

FIG. 1 is a block diagram illustrating a system configuration example for realizing a rotary tool diagnosis method according to a first embodiment of the present invention;

FIG. 2 is a diagram illustrating an example of a current waveform of an observed rotary tool;

FIG. 3 is a diagram illustrating an example of machining with a rotary tool;

FIG. 4 is a diagram illustrating a current waveform of each electric motor during machining with the rotary tool illustrated in FIG. 3;

FIG. 5 is a diagram illustrating an example of operation waveforms of respective units of a calculation control unit according to the first embodiment of the present invention;

FIG. 6 is a diagram illustrating a configuration example of a downlink transmission packet in the first embodiment of the present invention;

FIG. 7 is a block diagram illustrating a network configuration example of the rotary tool diagnosis system according to the first embodiment of the present invention;

FIG. 8 is a block diagram illustrating a system configuration example for realizing a rotary tool diagnosis method according to a second embodiment of the present invention;

FIG. 9 is a diagram illustrating an example of operation waveforms of respective units of a calculation control unit according to the second embodiment of the present invention; and

FIG. 10 is a block diagram illustrating a system configuration example for realizing a rotary tool diagnosis method according to a third embodiment of the present invention.

### DESCRIPTION OF THE PREFERRED EMBODIMENTS

Preferred embodiments of the present invention will be described in detail below with reference to the accompanying drawings. In the accompanying drawings, components having substantially the same function or configuration are denoted by the same reference numerals, and redundant description will be omitted.

### 1. First Embodiment

First, a first embodiment of the present invention will be described. A rotary tool diagnosis system according to the present embodiment is a system for diagnosing the soundness of a processing machine (for example, a rotary tool) including a plurality of electric motors for moving and processing a workpiece by measuring its drive current.

Generally, when a workpiece is processed using a processing machine, the workpiece is moved to a predetermined position and then processed with a rotary tool. The present invention has been made in view of this work. Specifically, the present invention monitors current waveforms of a plurality of electric motors provided in the same processing machine, records the current waveform of the main motor that drives a rotary tool, using the current waveform of each electric motor as a trigger, and performs diagnosis based on the current waveform.

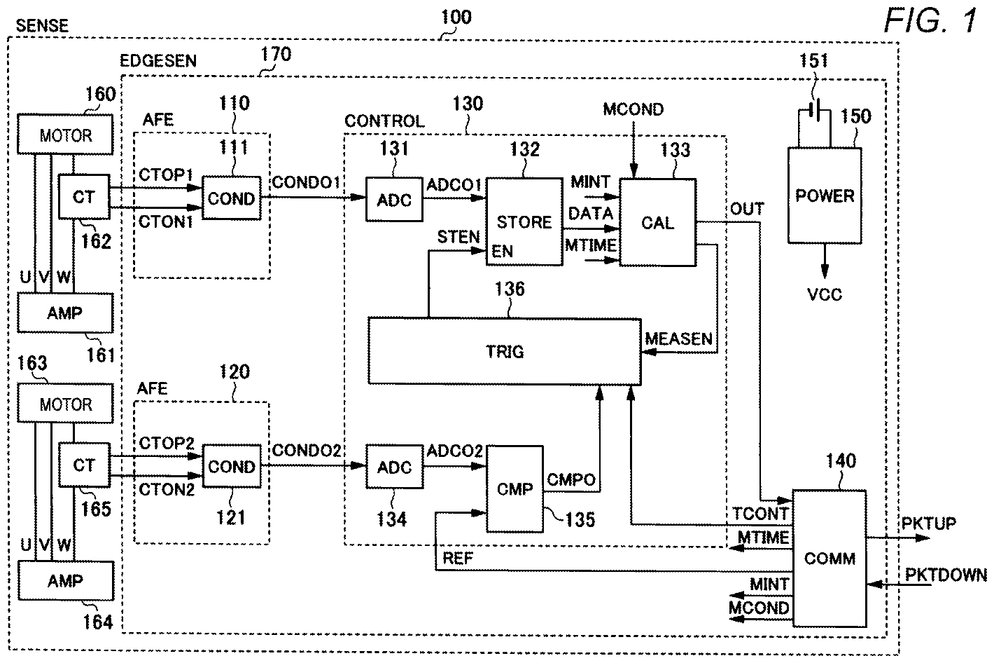

FIG. 1 is a block diagram illustrating a system configuration example for realizing the rotary tool diagnosis method according to the first embodiment of the present invention. A diagnostic unit 100 includes a plurality of electric motors 160 and 163, servo amplifiers 161 and 164, current detectors (current transformers: CT) 162 and 165 attached to power lines connected to the electric motors 160 and 163, and a signal processing device 170. The diagnostic unit 100 can be said to be an example of the minimum unit rotary tool diagnosis system.

In FIG. 1, the diagnostic unit is represented as “SENSE”, the electric motor as “Motor”, the servo amplifier as “AMP”, the current detector as “CT”, and the signal processing device as “EDGESEN”. In the present embodiment, three-phase AC motors are used for the electric motor 160 and the electric motor 163.

The electric motor 160 (first electric motor) is connected to the servo amplifier 161 (first servo amplifier) by three power lines (U phase, V phase, W phase, respectively) and driven by a three-phase AC power source supplied from the servo amplifier 161. The electric motor 160 is a main electric motor (an example of a direct diagnosis target) that is connected to a main shaft of a rotary tool such as an end mill and rotates the rotary tool.

Further, the electric motor 163 (second electric motor) is connected to the servo amplifier 164 (second servo amplifier) by three power lines (U phase, V phase, W phase, respectively) and driven by a three-phase AC power source supplied from the servo amplifier 164. The electric motor 163 is an electric motor that is disposed in the rotary tool and moves the position of the base material (workpiece) relative to the rotary tool.

In the present embodiment, as an example, the current detector 162 (first current detector) is provided on the W-phase power line of the electric motor 160, the current detector 165 (second current detector) is provided in the W-phase power line of the electric motor 163, and each W phase current can be monitored independently. The current detector 162 outputs currents CTOP1 and CTON1 corresponding to the detected current, and the current detectors 162 and 165 output currents CTOP2 and CTON2 corresponding to the detected current. The two electric motors 160 and 163 are components of the same machine tool, and the electric motor 163 controls the height Z (digging depth) of the X-Y stage or the rotary tool, and the electric motor 160 serves to rotate the rotary tool.

The current detector needs to be appropriately selected according to the magnitude of the current flowing through the electric motor (three-phase AC motor in this example). If a current detector with a small allowable current capacity is applied to an electric motor with a large current capacity, the current detector may be damaged. Conversely, if a current detector with a large allowable current capacity is applied to an electric motor with a small current capacity, a current signal cannot be detected. The current detector detects a current of at least one power line connected to the electric motor.

Next, a signal processing device 170 will be described.

The signal processing device 170 includes analog front ends 110 and 120, a calculation control unit 130, a communication circuit 140, and a power supply circuit 150. In FIG. 1, the analog front end is denoted as “AFE”, the calculation control unit as “CONTROL”, the communication circuit as “COMM”, and the power supply circuit as “POWER”. All the blocks are configured by analog circuits and digital circuits (hardware) or software.

The current CTOP1 and the current CTON1 output from the current detector 162 are input to an input circuit 111 (denoted as “COND” in FIG. 1) of the analog front end 110. Further, the current CTOP2 and the current CTON2 output from the current detector 165 are input to an input circuit 121 of the analog front end 120. The output CONDO1 of the analog front end 110 and the output CONDO2 of the analog front end 120 are input to the calculation control unit 130.

The analog front end 110 (first analog front end) includes the input circuit 111. The input circuit 111 performs level conversion and input filtering on the currents CTOP1 and CTON1 input from the current detector 162. Similarly, the analog front end 120 (second analog front end) includes the input circuit 121. The input circuit 121 performs level conversion and input filtering on the currents CTOP2 and CTON2 input from the current detector 165. As a result, the analog front ends 110 and 120 take out signals in the necessary bands from the outputs of the current detectors 162 and 165, and can prevent damage to the calculation control unit 130 by matching the voltage conversion range of analog to digital conversion and the signal voltage level.

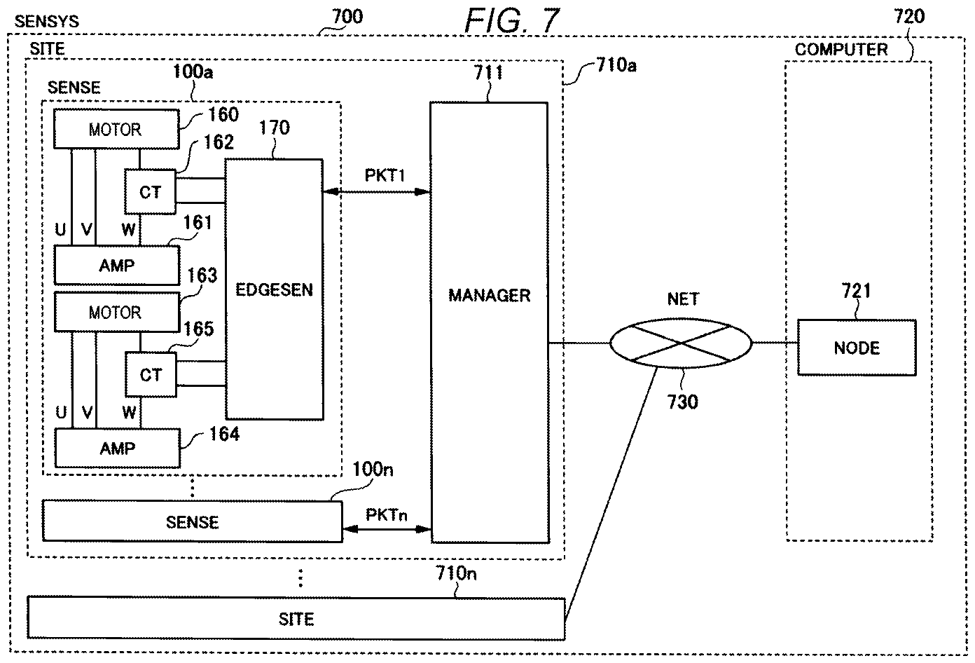

The operation control value included in a packet PKTDOWN received by the communication circuit 140 from the host system (cloud computer 720: refer to FIG. 7) is input to the calculation control unit 130. For example, the packet PKTDOWN includes information on a reference level REF, a timer count set value TCONT, a measurement count MTIME, a measurement interval MINT, and an output calculation condition MCOND.

The reference level REF is a threshold used in the comparison process by a comparator 135. The timer count set value TCONT is information for setting the ON time of a trigger output unit 136. The number of times of measurement MTIME is a value indicating how many times the current waveform of the electric motor 160 is measured within a specified time or while a rotary tool is being used. The measurement interval MINT is a value indicating an interval from one measurement to the next measurement when the current waveform is measured a plurality of times under the above conditions. The output calculation condition MCOND is information indicating how to combine the above information input to the calculation control unit 130 to obtain an output OUT of the output calculation unit 133, and whether to perform processing on the measurement data DATA.

The calculation control unit 130 includes an analog-digital converter 131, a data recording unit 132, an output calculation unit 133, an analog-digital converter 134, the comparator 135, and the trigger output unit 136. In FIG. 1, the analog-digital converter is denoted as “ADC”, the data recording unit as “STORE”, the output calculation unit as “CAL”, the comparator as “CMP”, and the trigger output unit as “TRIG”.

The analog-digital converter 131 digitizes the output CONDO1 of the input analog signal to obtain an output ADCO1. The output ADCO1 of the analog-digital converter 131 is supplied to the data recording unit 132.

The analog-digital converter 134 digitizes the output CONDO2 of the input analog signal to obtain an output ADCO2. The output ADCO2 of the analog-digital converter 134 is supplied to the comparator 135.

The comparator 135 (an example of a comparison unit) compares the output ADC2O of the analog-to-digital converter 134 with a reference level REF (threshold) set from the communication circuit 140 and obtains a comparison result CMPO as a result of processing for the output ADC2O. The comparison result CMPO is input to the trigger output unit 136. When the value of the output ADC2O exceeds the reference level REF, the comparator 135 notifies the trigger output unit 136 that the value of the output ADC2O exceeds the reference level REF by setting the comparison result CMPO to “High”. A measurement enable signal MEASEN output from the output calculation unit 133 is also input to the trigger output unit 136.

The trigger output unit 136 operates only once with the comparison result CMPO as a trigger while the measurement enable signal MEASEN is “High” and outputs a signal STEN (recording execution signal) indicating that the trigger output unit 136 is operating. The operation period is a period specified by the timer count set value TCONT. Note that, in the present embodiment, the operation is performed only once using the comparison result CMPO as a trigger. However, the operation may be performed a plurality of times.

When the signal STEN indicating that the trigger output unit 136 is operating is input to the data recording unit 132, the data recording unit 132 records a signal of the output ADCO1 of the analog-digital converter 131 As the data recording unit 132, for example, a nonvolatile semiconductor memory or a volatile semiconductor memory can be used. Then, the recorded signal of the output ADCO1 is output from the data recording unit 132 to the output calculation unit 133 as measurement data DATA.

The measurement data DATA, the number of times of measurement MTIME, the measurement interval MINT, and the output calculation condition MCOND are input to the output calculation unit 133. The output calculation unit 133 issues the measurement enable signal MEASEN at the number of times of measurement MTIME, the measurement interval MINT, and the number of times and intervals determined by the output calculation condition MCOND.

Further, the output calculation unit 133 performs amplitude component extraction, frequency analysis, encoding, frequency component extraction processing, security processing for output, and the like on the measurement data DATA based on the output calculation condition MCOND, and obtains the output OUT. The output calculation unit 133 can be configured by various mounting methods such as a digital signal processor (DSP), a hardware logic circuit, and software operating on a microcomputer.

The communication circuit 140 transmits, on the uplink to the host system (cloud computer 720 in FIG. 7) via a communication network 730, a packet PKTUP including information on the output OUT of the calculation control unit 130 as a recording result of ADCO1 by the data recording unit 132. The host system is an example of an external device. Note that the output calculation unit 133 may output and display the output OUT on a display device (not illustrated) included in the diagnostic unit 100.

For example, a battery 151 is connected to the power supply circuit 150, and the power supply circuit 150 generates a power supply voltage VCC that operates each circuit in the signal processing device 170. The voltage value of the power supply voltage VCC is monitored and collected from the communication circuit 140 to the host system (cloud computer 720) as battery remaining amount information using, for example, a radio signal. As a result, a down (operation stop) due to the remaining battery level of the wireless terminal due to a decrease in the power supply voltage VCC can be predicted, and battery replacement can be performed at an appropriate timing. The battery remaining amount information may be output to a display device (not illustrated) included in the diagnostic unit 100.

In the present embodiment, since the signal of the output ADCO1 on the electric motor 160 side is recorded for a necessary time, the power consumption of the battery 151 is suppressed, and the signal processing device 170 can be stably driven even when the battery 151 is used. Note that the battery 151 is used for example, and an energy harvesting facility such as a solar cell (not illustrated) may be disposed such that the power supply circuit 150 obtains the power supply voltage VCC from the energy harvesting facility. The energy harvesting facility may be used in combination with the battery 151.

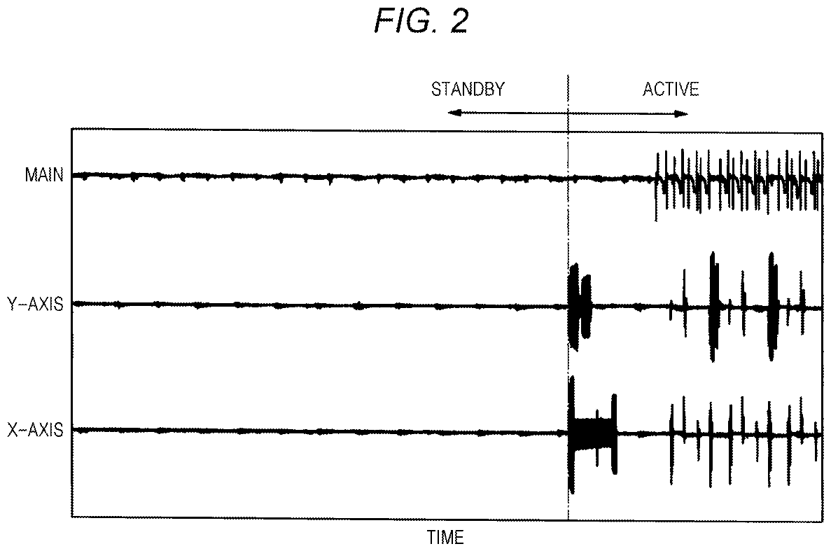

FIG. 2 shows an example of the current waveform of a rotary tool observed using a current detector. In FIG. 1, the current waveform of the electric motor 160 that drives the rotary tool is Main, and the current waveforms of the X-axis and Y-axis of the X-Y stage are X-axis and Y-axis. The horizontal axis of each waveform diagram illustrated in FIG. 1 is time. The output of the current detector 162 in FIG. 1 can be considered as Main, and the output of the current detector 165 can be considered as X-axis or Y-axis. A Y-axis may be measured by adding a separate current detector (third current detector) and analog front end (third analog front end) to the diagnostic unit 100 in FIG. 1. Further, the output of the current detector 165 or the output of a third current detector added separately may be a Z-axis current waveform (Z-axis).

As can be seen from FIG. 2, when the rotary tool is moved in the X-axis or Y-axis direction in a standby state (“Standby” in drawing), processing by the electric motor 160 starts after a change appears in the X-axis or Y-axis current waveform (“Active” in the drawing). FIG. 2 shows an example in which the rotary tool is moved in an oblique direction with respect to the X axis and the Y axis. When the main current waveform is recorded in the entire time zone illustrated in FIG. 2, about ¾ of the current waveform becomes useless data, and the storage capacity of the data recording unit 132 is wasted uselessly. As a result, data processing for selecting a meaningless data area is also required. On the other hand, by capturing the Main waveform triggered by the fact that the current waveform of the X axis or Y axis exceeds a certain level, it becomes possible to select and record only the necessary data.

In general, in a machine tool, a workpiece is first moved to a predetermined position and then processed by a rotary tool. Since the movement of the workpiece to the predetermined position is also performed by an electric motor in the same manner as the machining, in the present invention, movement of the workpiece to the predetermined position is detected by measuring the current waveform of the electric motor that moves the X-Y stage, and the data necessary for diagnosis of the rotary tool is obtained.

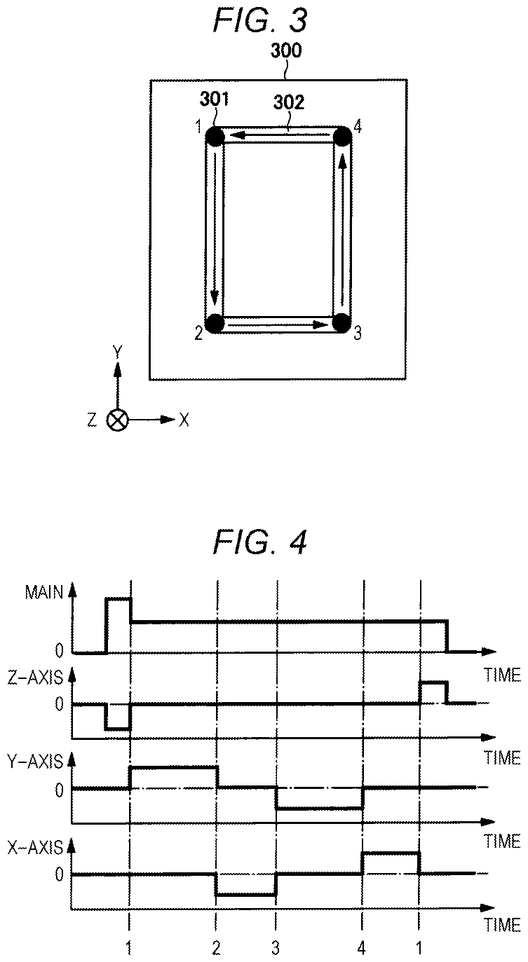

FIG. 3 illustrates an example of machining with a rotary tool.

FIG. 4 illustrates an example of a current waveform of each electric motor during machining by the rotary tool in FIG. 3.

FIG. 3 illustrates an example in which a groove 302 is processed along a square side in a base material 300 (workpiece) by an end mill 301, and the base material 300 is viewed from above in the drawing. FIG. 4 schematically illustrates the magnitude of the current waveform (torque current) of each electric motor in the above machining. The positive directions of the X-axis, Y-axis, and Z-axis are as illustrated in FIG. 3. The horizontal axis of each waveform diagram illustrated in FIG. 1 is time. The end mill 301 starts machining from the initial position 1, moves from position 1→position 2→position 3→position 4, and finally returns to position 1 to finish the machining.

First, at position 1, a torque is generated in the negative direction of the Z-axis motor to move the electric motor 160, which is the main motor, to the Z-axis, and the base material 300 is processed by the end mill 301. Since the hole is dug at this time, the initial torque current of the torque current Main of the electric motor 160 increases.

Next, in the machining in which the end mill 301 moves from position 1 to position 2, the torque current Main of the electric motor 160 is constant, and the XYZ stage is moved along the machining direction indicated by the arrow (Y-axis negative direction). While the XYZ stage is moving, the torque current of the motor provided on each axis of the XYZ stage has positive and negative values.

Then, similarly, the groove 302 is formed in the base material 300 along a square side by performing machining that the end mill 301 is moved from position 2 to position 3 (X axis positive direction), machining that the end mill 301 moves from position 3 to position 4 (Y-axis positive direction), and machining that the end mill 301 moves from position 4 to position 1 (X-axis negative direction).

According to the rotary tool diagnosis method of the present invention, for example, when the current waveform of the electric motor of the torque current Main is recorded for a predetermined time from when the torque current of the Z-axis motor exceeds the negative threshold, it becomes possible to observe only a large torque current that appears in the torque current Main of the electric motor 160 when machining starts. Although the actual waveform of the torque current depends on the shape of machining and the material of the base material 300, the deterioration of a rotary tool can be diagnosed by acquiring only the current waveform when a load increases. In this manner, it becomes possible to efficiently diagnose deterioration without acquiring all current waveforms during processing.

Further, when it is desired to acquire a current waveform only when the direction of the end mill 301 is changed, the operation of starting the recording of the Main current waveform may be performed based on the X-axis or Y-axis torque current threshold. If it is understood that deterioration is more severe when machining while changing direction and digging than when machining in a straight line, a method of obtaining a current waveform is effective only when this direction is changed.

Since the shape and process of machining can be seen from the outside without a program, it is possible to trigger measurement of the current waveform of the Main (main motor) in accordance with the timing when a load is relatively most applied to a rotary tool. The present invention includes such a method in its technical scope.

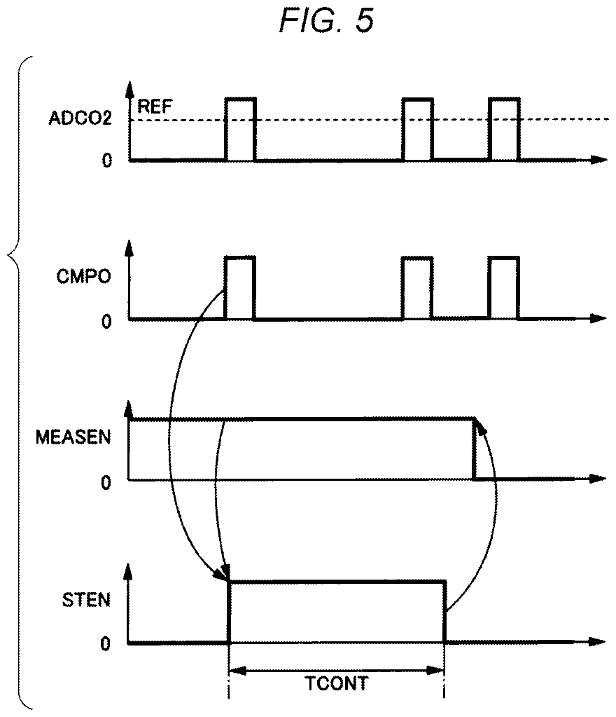

FIG. 5 illustrates an example of the operation waveform of each part of the calculation control unit 130. The output ADCO2 of the analog-digital converter 134, which is a system of the electric motor 160, periodically becomes an output exceeding the reference level REF. When the output ADCO2 first exceeds the reference level REF, the output CMPO of the comparator 135 becomes “High”. Since the measurement enable signal MEASEN output from the output calculation unit 133 is “High” in advance, the trigger output unit 136 triggers a one-shot timer function in response to the transition (High) of the output CMPO of the comparator 135, and the timer function is activated in advance for the timer count set value TCONT. As a result, a signal STEN output from the trigger output unit 136 becomes “High” for the time of the timer count set value TCONT. During the period when the signal STEN is “High”, the data of the output ADCO1 from the analog-digital converter 131 is continuously recorded in the data recording unit 132.

The signal STEN output from the trigger output unit 136 becomes “Low” when the one-shot timer count ends (time of the timer count set value TCONT elapses). Thereby, one measurement of the current waveform of the electric motor 160 is completed.

In this way, the trigger output unit 136 operates once as a trigger on the result of the comparison process for the output current signal of the current detector 165, by outputting the recording execution signal STEN for the specified time (TCONT), data is recorded as many times as necessary and as long as necessary based on actual machining.

Whether the next measurement is started depends on the level of the measurement enable signal MEASEN. The output calculation unit 133 controls the measurement enable signal MEASEN to have a preset measurement cycle (measurement interval MINT) and the number of times of measurement MTIME. That is, the waveform of the measurement enable signal MEASEN is repeated at a predetermined cycle. In the example illustrated in FIG. 5, the measurement enable signal MEASEN is “Low” at the timing when the output ADCO2 exceeds the reference level REF for the third time. Therefore, the signal STEN output from the trigger output unit 136 remains “Low”, and the current waveform (output ADCO1) of the electric motor 160 is not measured, that is, recorded.

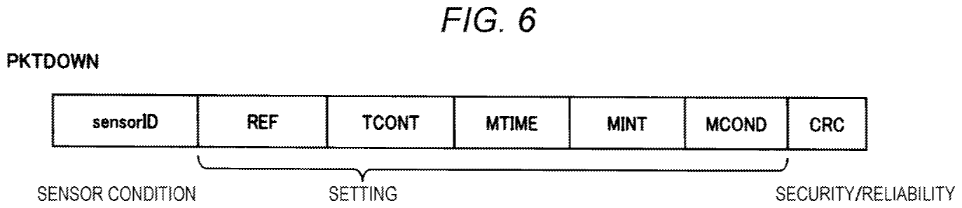

FIG. 6 illustrates a configuration example of a downlink transmission packet in the first embodiment of the present invention. FIG. 6 is a configuration example of the packet PKTDOWN received on the downlink from the host system (cloud computer 720 in FIG. 7). For example, the packet PKTDOWN includes information (Sensor Condition) for indicating a sensor state, setting data (Setting) for measurement, and information for ensuring reliability (Security/Reliability).

The information for indicating the sensor state (Sensor Condition) includes, for example, an identifier “sensorID” for identifying the information. “sensorID” is information (number, symbol, etc.) that can identify a diagnostic unit (sense). Further, the setting data (Setting) includes, for example, various setting data such as a reference level “REF”, a timer count setting value “TCONT”, the number of times of measurement “MTIME”, a measurement interval “MINT”, and an output calculation condition “MCOND”. In addition, as information for ensuring reliability (Security/Reliability), for example, CRC information is included.

The reception timing of the packet PKTDOWN including these pieces of information is when the signal processing device 170 is disposed or when the setting information (operation setting value) of the signal processing device 170 may be changed. During normal operation, it is not necessary to set these values for each communication timing and to receive as a downlink. Since downlink is expensive in communication cost (high power consumption), it is preferable to perform the downlink at the minimum necessary.

FIG. 7 is a block diagram illustrating a network configuration example of the rotary tool diagnosis system according to the first embodiment of the present invention. A rotary tool diagnosis system 700 illustrated in FIG. 7 can monitor a plurality of rotary tools from a remote location.

The rotary tool diagnosis system 700 includes a plurality of measurement sites 710a to 710n, the communication network 730, and the cloud computer 720. Depending on the system configuration, only one measurement site 710a may be provided.

In FIG. 7, the rotary tool system is denoted as “SENSYS”, the measurement site as “SITE”, the communication network 730 as “NET”, and the cloud computer as “COMPUTER”. In the following description, when the measurement sites 710a to 710n are not distinguished, they are referred to as “measurement sites 710”. When the diagnostic units 100a to 100n are not distinguished, they are referred to as “diagnostic unit 100”.

Each of the measurement sites 710a to 710n includes a plurality of diagnostic units 100a to 100n and a data collection device 711 that collects packets PKT1 to PKTn (corresponding to PKTUP in FIG. 1) from a plurality of the diagnostic units 100. Based on an instruction from the cloud computer 720, the data collection device 711 transmits packets PKT1 to PKTn (corresponding to the packet PKTDOWN in FIG. 1) including setting information such as operation setting values to each of the diagnostic units 100a to 100n. FIG. 7 shows the configuration of one measurement site 710a, but the other measurement sites 710b to 710m have the same configuration. In FIG. 7, the data collection device is denoted as “MANAGER”.

The number of the diagnostic units 100 is designed according to the number of processing machines in the measurement site 710 and the limit number of measurement sites at which the data collection device 711 can collect packets. Depending on the system configuration, only one diagnostic unit 100a may be provided.

One diagnostic unit 100 includes, for example, the electric motors 160 and 163, the servo amplifiers 161 and 164, the current detectors 162 and 165, and the signal processing device 170. The communication circuit 140 (refer to FIG. 1) included in the signal processing device 170 of each diagnostic unit 100a to 100n outputs packets PKT1, . . . , PKTn containing measurement data (output OUT) of the electric motor 160 that is a main electric motor. The data collection device 711 at each measurement site 710 transmits the packets PKT1, . . . , PKTn collected (received) from the diagnostic units 100a to 100n to the cloud computer 720 via the communication network 730.

The cloud computer 720 accumulates data received from the measurement sites 710a to 710n. Then, various processes such as a diagnosis process using the accumulated data are performed in the calculation node 721 of the cloud computer 720. Note that the information of the calculation node 721 is referred to from a monitoring system (terminal device) (not illustrated) that monitors a rotary tool and is used for operations according to the deterioration status of the rotary tool. Further, since the information accumulated in the cloud computer 720 can be referred to separately on a tablet terminal or the like via the communication network 730, it can be used for checking the deterioration of a rotary tool at the site.

According to the first embodiment described above, by monitoring the current waveform of the electric motor 163 different from the electric motor 160 of the main motor, without coordinating with a machining program and machining sequence of a processing machine, it is possible to diagnose a rotary tool by grasping the operation timing of the rotary tool with a simple configuration as compared with the conventional configuration. Therefore, the diagnostic function of the rotary tool can be realized at a low cost without a large-scale modification to the processing machine or the like. As described above, in the present embodiment, by preparing the signal processing device 170 by disposing a low-cost IoT (Internet of Things) device such as a current detector that detects the current of a power line of an electric motor in the processing machine, it is possible to diagnose deterioration of a rotary tool.

Further, according to the present embodiment, by monitoring the current waveform of the electric motor 163, data for performing diagnosis of the rotary tool (the output ADCO1 on the electric motor 160 side) can be recorded for a necessary time based on actual machining. Thereby, the storage capacity and calculation capacity of the signal processing device 170 are kept low, and signal processing and data communication necessary for diagnosis of a rotary tool can be performed within a small power range that can be driven by a battery, for example.

Furthermore, according to the present embodiment, based on the measurement data of the rotary tool collected from the signal processing device 170 of each diagnostic unit 100, the rotary tool diagnosis is realized at low cost by the cloud computer 720 and the monitoring system (terminal device). As a result, the rotary tool can be used for an appropriate time and number of times while suppressing deterioration of the machining quality, and the manufacturing cost can be reduced.

Note that the diagnostic unit 100 may include a combination of three or more current detectors and analog front ends (not illustrated). For example, the signal processing device 170 is provided with a third analog front end (not illustrated) and a second comparator, and an output current signal from a third current detector attached to a power line of a third electric motor (not illustrated) of the rotary tool is input to the calculation control unit 130 via the third analog front end. The second comparator of the calculation control unit 130 compares the output CONDO3 (not illustrated) of the third analog front end with the second reference level REF2 (not illustrated), and when the output CONDO3 is larger than the second reference level REF2, it is input to the trigger output unit 136 as the output CMPO2 (not illustrated). When “High” is input as the output CMPO from the comparator 135 and the output CMPO2 from the second comparator, the trigger output unit 136 changes the signal STEN to “High” in accordance with the signal level of the measurement enable signal MEASEN.

### 2. Second Embodiment

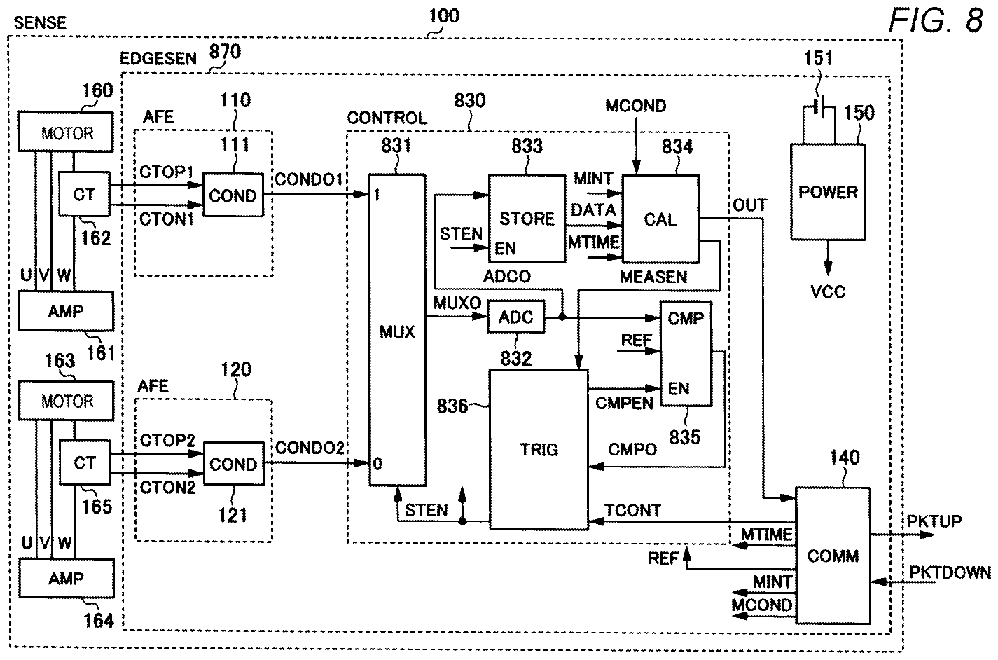

FIG. 8 is a block diagram illustrating a system configuration example for realizing a rotary tool diagnosis method according to the second embodiment of the present invention. Compared to the case of the first embodiment illustrated in FIG. 1, a signal processing device 870 according to the second embodiment is greatly different in that a selection unit 831 receives an output CONDO1 of an analog front end 110 and an output CONDO2 of an analog front end 120.

The signal processing device 870 includes the analog front ends 110 and 120, a calculation control unit 830, a communication circuit 140, and a power supply circuit 150.

The calculation control unit 830 includes the selection unit 831, an analog-digital converter 832, a data recording unit 833, an output calculation unit 834, a comparator 835 (an example of a comparison unit), and a trigger output unit 836. In FIG. 8, the selection unit is denoted as “MUX”.

The selection unit 831 selectively switches between “1” that captures the output CONDO1 of the analog front end 110 and “0” that captures the output CONDO2 of the analog front end 120, and outputs one of the analog signals as an output MUXO. As an initial value, the output CONDO2 of the analog front end 120 is selected.

Each of the analog-digital converter 832, the data recording unit 833, and the output calculation unit 834 has the same configuration and function as the analog-digital converters 131 and 134, the data recording unit 132, and the output calculation unit 133 (refer to FIG. 1). The data recording unit 833 captures a digital signal output ADCO of the analog-digital converter 832 and outputs a signal of the output ADCO as measurement data DATA to the output calculation unit 834.

The comparator 835 has substantially the same configuration and function as the comparator 135. The comparator 835 compares the output ADCO of the analog-digital converter 832 with a reference level REF (threshold) set from a communication circuit 140 and obtains a comparison result CMPO. The comparison result CMPO is input to the trigger output unit 836. The trigger output unit 836 also receives a measurement enable signal MEASEN output from the output calculation unit 834.

The trigger output unit 836 also has substantially the same configuration and function as the trigger output unit 136. The trigger output unit 836 operates only once with the comparison result CMPO as a trigger while the measurement enable signal MEASEN is “High”, and outputs a signal STEN (recording execution signal) indicating that the trigger output unit 836 is operating. The operation period is a period corresponding to a timer count set value TCONT. The signal STEN indicating that the trigger output unit 836 is operating is input to the selection unit 831 and the data recording unit 833.

In the calculation control unit 830 configured as described above, “0” is selected by the selection unit 831 in the initial state, and the output CONDO2 on the current detector 165 side is output from the selection unit 831 to the analog-digital converter 832 as the output MUXO. Then, the output MUXO that is an analog signal is converted into a digital value by the analog-digital converter 832. According to the comparison result CMPO in which the output ADCO converted into a digital value is compared with the reference level REF by the comparator 835, the trigger output unit 836 is activated, and the signal STEN indicating that the trigger output unit 836 is operating is output to the selection unit 831.

When the signal STEN indicating that the trigger output unit 836 is operating is input to the selection unit 831, in the trigger output unit 836, the selection is changed from “0” (current detector 165 system) to “1” (current detector 162 system). Then, similarly, the output ADCO on the current detector 162 side is captured by the data recording unit 833 that is enabled by the signal STEN. Other configurations of the calculation control unit 830 are the same as those of the calculation control unit 130 in FIG. 1.

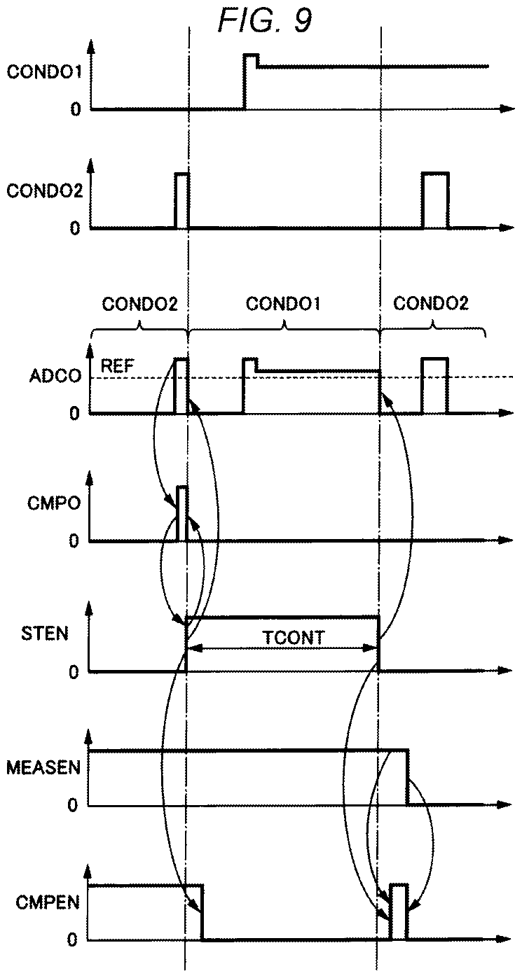

FIG. 9 illustrates an example of the operation waveform of each part of the calculation control unit 830. The content of the output ADCO of the analog-digital converter 832 is switched to either the output CONDO1 or the output CONDO2 by the selection of the selection unit 831 based on the signal STEN. When the output ADCO is not recorded in the data recording unit 833, the output CONDO2 is selected by the selection unit 831.

When the output CONDO2 is selected by the selection unit 831 and the output ADCO exceeds the reference level REF, the comparison result CMPO output from the comparator 835 becomes “High”. In response to the comparison result CMPO transitioning to “High”, the signal STEN indicating that the trigger output unit 836 is operating is set to “High”, the trigger of a one-shot timer of the trigger output unit 836 is activated to start counting. The count continues for a period determined by the timer count set value TCONT, and the signal STEN indicating that the trigger output unit 836 is operating is “High” during the time the counter is operating.

Then, in response to the transition of the signal STEN to “High”, the output CMPEN of the trigger output unit 836 becomes “Low” after a predetermined time delay, and the operation of the comparator 835 stops. The reason for this operation is to prevent the comparator 835 from performing the comparison operation when the selection of the selection unit 831 is switched from “0” to “1”, that is, when the selection unit 831 selects the output CONDO2 on the side of a motor 163 that is the main motor. Thereby, malfunction of the one-shot timer of the trigger output unit 836 based on the current waveform of the output CONDO1 on the electric motor 160 side can be avoided.

When the count of the one-shot timer of the trigger output unit 836 (timer count set value TCONT) ends, the signal STEN becomes “Low”. In response to this, if the measurement enable signal MEASEN is “High”, the output CMPEN of the trigger output unit 836 becomes “High” after a predetermined time delay, and the operation of the comparator 835 is resumed. In the example of FIG. 8, the waveform of the measurement enable signal MEASEN is also “Low”. At this time, the output CMPEN becomes “Low” in response to the transition of the measurement enable signal MEASEN to “Low”, and the comparator 835 turns off. In this state, even if the output CONDO2 subsequently exceeds the reference level REF, the signal STEN indicating that the trigger output unit 836 is operating does not transition to “High”, and the data recording unit 833 does not shift to a recording operation.

According to the above-described second embodiment, a signal processing device 170 triggers based on the processing result for the output signal of the current detector 165, switches to the output signal of the current detector 162 by the selection unit 831, and starts recording of the output signal from the current detector 162. By adopting a configuration in which one analog-digital converter 832 is shared by a plurality of motors, the circuit scale can be reduced as compared with the first embodiment. Further, when the selection unit 831 selects the output CONDO1 on the side of the electric motor 160, which is the main motor, the comparator 835 does not perform the comparison operation, such that the trigger output unit 836 can be prevented from malfunctioning due to the waveform of the output CONDO1. When the selection unit 831 selects the output CONDO2 on the electric motor 163 side, the output CONDO1 is not input to the analog-digital converter 832 and the data recording unit 833, such that power consumption can be reduced.

Note that the diagnostic unit 100 may include a combination of three or more current detectors and analog front ends (not illustrated). For example, the signal processing device 870 is provided with a third analog front end (not illustrated), and the output current signal from the third current detector attached to the power line of the third electric motor (not illustrated) of the rotary tool is received and input to the selection unit 831 via the third analog front end. The selection unit 831 inputs a signal obtained by logical product or logical sum of the output CONDO2 of the analog front end 120 and the output CONDO3 (not illustrated) of the third analog front end to the ADC 832 when the initial setting is “0”.

### 3. Third Embodiment

In the configuration described above, the power supply circuit 150 included in the signal processing device according to the first embodiment and the second embodiment includes a battery 151 or energy harvesting. On the other hand, as the power supply circuit 150, a current detected from a power line connected to an electric motor 163 may be used as a power supply.

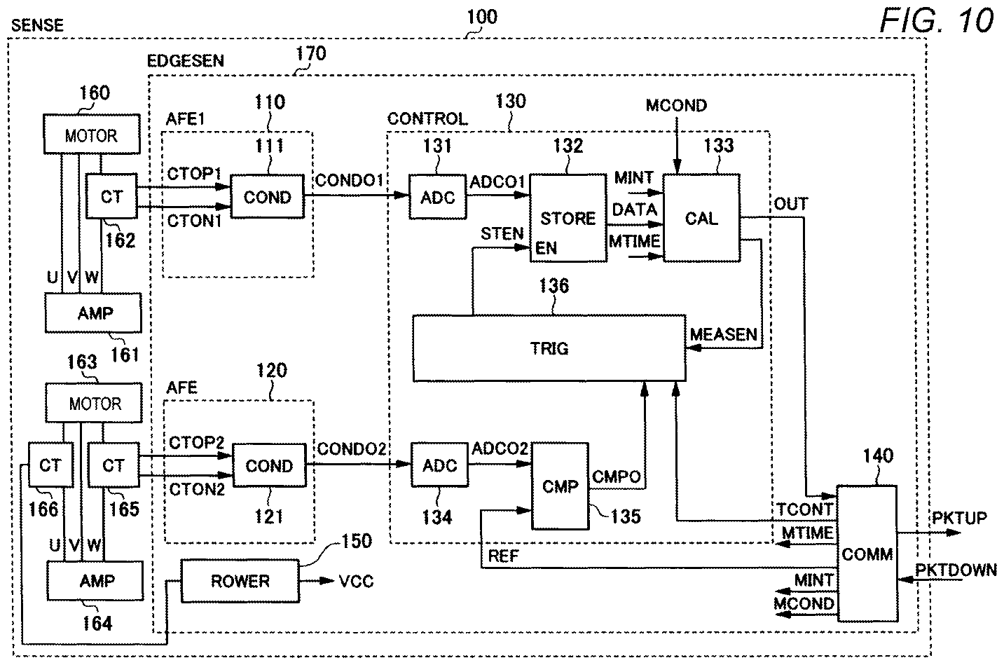

FIG. 10 is a block diagram illustrating a system configuration example for realizing a rotary tool diagnosis method according to the third embodiment of the present invention. As illustrated in FIG. 10, a current detector 166 (fourth current detector) is disposed on a U-phase power line of an electric motor 160, and the current obtained by the current detector 166 is supplied to the power supply circuit 150. In the example of FIG. 10, a current detector 165 is provided in the diagnostic unit 100 (refer to FIG. 1) including the signal processing device 170 according to the first embodiment. Obtaining a current from the U-phase power line is an example, and other phase power lines may be used. However, it is preferable to obtain a current from a power line of a phase different from that of the current detector 165 for detecting an abnormality.

Then, the power supply circuit 150 obtains a power supply voltage VCC for operating the signal processing device 170 from the current obtained by the current detector 166. Other configurations of the signal processing device 170 illustrated in FIG. 10 are the same as those of the signal processing device 170 illustrated in FIG. 1.

As described above, the power source for operating the signal processing device 170 is obtained from the power for driving the electric motor 163. Thereby there is an advantage that the battery 151 (battery replacement), energy harvesting and the like are not required, maintenance costs are reduced, and the configuration of the power supply circuit can be simplified. Note that the current detector 166 may be disposed on the power line of the electric motor 160 to detect a current and generate a power source. However, it can be said that it is preferable to obtain a current from the electric motor 163 that is not a measurement target.

### 4. Variation

Note that the present invention is not limited to each of the above-described embodiments, and other various applications and variations are applicable within the gist of the present invention described in “What is claimed is”.

For example, the above-described embodiment describes a device/system configuration in detail and specifically for clarifying the present invention, and every configuration described above may not be necessarily included. Further, a part of the configuration of one embodiment can be replaced with the configuration of another embodiment. In addition, the configuration of one embodiment can be added to the configuration of another embodiment. Further, a part of the configuration of each embodiment can also be added to, deleted from, and replaced from the other configuration.

Further, in the configuration diagrams and functional block diagrams, control lines and information lines which are considered to be necessary for description are indicated, and all of control lines and information lines on the product are not necessarily indicated. It may be considered that almost all of the configurations are actually connected each other.

Further, each of the configurations, functions, process units, and process means, which have been explained in each of the above-described embodiments, may be realized by a hardware, for example, by designing a part of or all of them by using an integrated circuit. Further, each of the configurations which have been explained in each of the embodiments may be realized by software by a processor interpreting and performing a program for realizing each function. For example, in the signal processing device 170 according to the first embodiment, the data recording unit 132, the output calculation unit 133, the comparator 135, and the trigger output unit 136 can be realized by software. Information such as a program and the like for realizing each function can be stored in a recording device such as a memory, a hard disc, and a solid state drive (SSD) or a recording medium such as an IC card, an SD card, and an optical disk.

1. A rotary tool diagnosis system, comprising:
a first current detector configured to detect a current of at least one power line connected to a first electric motor that rotates a rotary tool;
a second current detector configured to detect a current of at least one power line connected to a second electric motor that is used for moving the rotary tool; and
a signal processing device configured to trigger based on a result of processing on an output signal of the second current detector and start recording of an output signal from the first current detector.

2. The rotary tool diagnosis system according to claim 1,
wherein the signal processing device includes:
a trigger output unit configured to operate once using the processing result for the output signal of the second current detector as a trigger and output a recording execution signal for a specified time; and
a data recording unit configured to receive the recording execution signal output from the trigger output unit and record the output signal from the first current detector.

3. The rotary tool diagnosis system according to claim 2,
wherein the signal processing device includes
a comparator configured to notify the trigger output unit that the value of the output signal of the second current detector exceeds a threshold as a result of the processing for the output signal of the second current detector, when the value of the output signal of the second current detector is compared with the threshold, and the value of the output signal of the second current detector exceeds the threshold.

4. The rotary tool diagnosis system according to claim 1,
wherein the signal processing device includes
a communication circuit configured to transmit a recording result of the output signal of the first current detector by the data recording unit to an external device.

5. The rotary tool diagnosis system according to claim 1, comprising a power supply circuit configured to generate a power supply voltage from a battery,
wherein the signal processing device is driven with the power supply voltage generated by the power supply circuit.

6. The rotary tool diagnosis system according to claim 1, comprising
a power supply circuit configured to generate a power supply voltage from power obtained by detecting the current by a current detector other than the first current detector and the second current detector,
wherein the signal processing device is driven by the power supply voltage generated by the power supply circuit.

7. The rotary tool diagnosis system according to claim 4,
wherein the signal processing device receives an operation setting value from the external device using the communication circuit, such that the trigger output unit and the comparator are operated based on the received operation setting value.

8. The rotary tool diagnosis system according to claim 1,
wherein the signal processing device includes a selection unit configured to selectively switch output signals of the first current detector and the second current detector, and
the signal processing device is configured to trigger based on the processing result for the output signal of the second current detector to switch to the output signal of the first current detector by the selection unit, and start recording of the output signal from the first current detector.
